(19) United States
(12) Patent Application Publication
(10) Pub. No.: US 2023/0112974 A1
(43) Pub. Date: Apr. 13, 2023

(54) HAND, TRANSFER APPARATUS, AND SUBSTRATE PROCESSING APPARATUS

(71) Applicant: EBARA CORPORATION, Tokyo (JP)

(72) Inventors: Kotaro TOYOSAWA, Tokyo (JP); Kenichiro SAITO, Tokyo (JP); Kenichi TAKEBUCHI, Tokyo (JP); Kenichi SUZUKI, Tokyo (JP)

(21) Appl. No.: 17/929,810

(22) Filed: Sep. 6, 2022

(30) Foreign Application Priority Data
Oct. 11, 2021 (JP) 2021-167002
Oct. 11, 2021 (JP) 2021-167003
Oct. 11, 2021 (JP) 2021-167005

(51) Int. Cl. B25J 15/00

(52) U.S. Cl. CPC B25J 15/0014; B25J 11/0095

(57) ABSTRACT

A hand for holding the substrate includes a hand main body and a plurality of seating members mounted on the hand main body and on which the substrate is to be seated. Each of the plurality of seating member includes a shaft member supported to the hand main body and a lever member that is supported to the shaft member and includes a first end portion including a seating portion on which the substrate is to be seated and a second end portion disposed on a side opposite to the first end portion across the shaft member. At least a part of the plurality of seating members further includes a biasing member for giving a force of rotating the lever member to the lever member such that the second end portion moves downward and a seating sensor configured to detect an upward movement of the second end portion.

### TECHNICAL FIELD

This application relates to a hand, a transfer apparatus, and a substrate processing apparatus. This application claims priority from Japanese Patent Application No. 2021-167002, Japanese Patent Application No. 2021-167003, and Japanese Patent Application No. 2021-167005 filed on Oct. 11, 2021. The entire disclosure including the descriptions, the claims, the drawings, and the abstracts in Japanese Patent Application No. 2021-167002, Japanese Patent Application No. 2021-167003, and Japanese Patent Application No. 2021-167005 are herein incorporated by reference.

### BACKGROUND ART

Recently, for example, a substrate processing apparatus has been used for performing various processes on a substrate, such as a semiconductor wafer. An example of the substrate processing apparatus includes a Chemical Mechanical Polishing (CMP) apparatus for performing, for example, a polishing process on the substrate.

As described in PTL 1, the CMP apparatus includes, for example, a polishing device for performing a polishing process of a substrate, a cleaning device for performing a cleaning process and a drying process of the substrate, and a loading/unloading device that grips or releases the substrate to the polishing device and receives the substrate on which the cleaning process and the drying process have been performed by the cleaning device. Additionally, the CMP apparatus includes a transfer apparatus that transfers the substrate between the polishing device, the cleaning device, and the loading/unloading device. The CMP apparatus sequentially performs various processes of polishing, cleaning, and drying while transferring the substrate by the transfer apparatus.

Some transfer apparatuses include hands for holding substrates and driving mechanisms for moving the hands. The hand includes a plurality of pins on which the substrate is to be seated, and seating of the substrate on the pins is detected. For detection of seating of the substrate, an optical sensor that includes a light projector and a light receiver is used. For example, the light receiver is disposed in the pin, and the light projector is disposed at a predetermined position apart from the pin. When the substrate blocks between the light projector and the light receiver, seating of the substrate on the pins is detected.

Some transfer apparatuses include hands for holding substrates and driving mechanisms for moving the hands. The hand includes a plurality of pins on which the substrate is to be seated and a first blade on which the plurality of pins are mounted. When the substrate seated on the plurality of pins is gripped or released to a top ring of a polishing device, the top ring presses a membrane (a suction surface) against the top surface of the substrate and performs vacuum suction to receive the substrate. The hand includes a second blade disposed below the first blade so as to be opposed, and supports the first blade via elastic members, such as a plurality of springs, mounted on the second blade to absorb a pressing load from the top ring.

Some transfer apparatuses include hands for holding substrates and driving mechanisms for moving the hands. The hand includes a plurality of pins on which the substrate is to be seated. As described in PTL 2, each of the plurality of pins includes a first inclined surface inclined with respect to a horizontal direction and facing upward and a second inclined surface formed on the upper side of the first inclined surface, inclined with respect to the horizontal direction, and facing downward. When the seated position of the substrate is displaced due to an acceleration during transfer of the substrate, the transfer apparatus suppresses falling of the substrate by abutment of the end portion of the substrate on the second inclined surface.

### CITATION LIST

### Patent Literature

PTL 1: Japanese Unexamined Patent Application Publication No. 2010-50436

PTL 2: Japanese Unexamined Patent Application Publication No. 2014-175333

### SUMMARY OF INVENTION

### Technical Problem

However, the related art has room for improvement in improvement in accuracy of seating detection of a substrate.

That is, in the seating detection by the related art, the optical sensor is disposed in a seating region on which the substrate is to be seated. Since cleaning water used for the cleaning process and a slurry used for the polishing process are mixed in the seating region, there may be a case where the light of the optical sensor is diffusely reflected by the cleaning water or the slurry, and this results in false detection of substrate seating.

Therefore, an object of this application is to improve accuracy of seating detection of a substrate.

Additionally, the related art has room for improvement in further stable absorption of the pressing load from the top ring.

That is, in the related art, when the membrane of the top ring is pressed against the substrate, the whole first blade absorbs the pressing load. Accordingly, for example, when the membrane partially contacts the substrate, a part of the first blade is pressed down to incline the first blade, and thus possibly resulting in unstable absorption of the pressing load.

Therefore, an object of this application is to further stably absorb the pressing load from the top ring.

Additionally, the related art has room for improvement in suppressing falling of the substrate at reception of the substrate from the top ring and positioning the substrate in a predetermined seating region.

That is, at reception of the substrate from the top ring, supplying a fluid to the suction surface of the substrate suctioned to the membrane of the top ring separates the substrate from the membrane. In this case, when the substrate separates from the membrane with a horizontal state maintained, this causes no problem. However, there may be a case where, by separating the substrate from the membrane only at one side of the substrate, the inclined substrate moves down to the transfer apparatus. Even in this case, it is requested to receive the substrate from the transfer apparatus without falling and position the substrate in the predetermined seating region.

Therefore, an object of this application is to suppress falling of a substrate from a hand at reception of the substrate from a top ring and position the substrate in a predetermined seating region.

### Solution to Problem

According to one embodiment, there is disclosed a hand for holding a substrate that includes a hand main body and a plurality of seating members. The plurality of seating members are mounted on the hand main body and on which the substrate is to be seated. Each of the plurality of seating members includes a shaft member and a lever member. The shaft member is supported to the hand main body. The lever member is supported to the shaft member and has a first end portion and a second end portion. The first end portion includes a seating portion on which the substrate is to be seated. The second end portion is disposed on a side opposite to the first end portion across the shaft member. At least a part of the plurality of seating members further includes a biasing member and a seating sensor. The biasing member is for giving a force of rotating the lever member to the lever member such that the second end portion moves downward. The seating sensor is configured to detect an upward movement of the second end portion.

According to one embodiment, there is disclosed a hand for holding a substrate that includes a hand main body and a plurality of seating members. The plurality of seating members are mounted on the hand main body and on which the substrate is to be seated. Each of the plurality of seating members includes a shaft member, a lever member, a bearing, and an elastic member. The shaft member is supported to the hand main body. The lever member is supported to the shaft member and has a first end portion and a second end portion. The first end portion includes a seating portion on which the substrate is to be seated. The second end portion is disposed on a side opposite to the first end portion across the shaft member. The bearing is for supporting both end portions of the shaft member. The elastic member is for supporting the bearing.

According to one embodiment, there is disclosed a hand for holding a substrate that includes a hand main body, a plurality of seating members, a plurality of guiding members, and a plurality of positioning members. The plurality of seating members are mounted on the hand main body and on which the substrate is to be seated. The plurality of guiding members are mounted on the hand main body at predetermined intervals with one another so as to surround a seating region on which the substrate is to be seated. The plurality of positioning members are mounted on the hand main body at predetermined intervals with one another so as to surround the seating region. Each of the plurality of guiding members has a substrate receiving surface inclined downward toward the seating region. Each of the plurality of positioning members includes a positioning portion in contact with an outer edge of the seating region.

### BRIEF DESCRIPTION OF DRAWINGS

FIG. 1 is a plan view illustrating an overall configuration of a CMP apparatus as one example of a substrate processing apparatus according to one embodiment of the present invention;

FIG. 2 is a perspective view schematically illustrating a polishing device;

FIG. 3(a) and FIG. 3(b) are a plan view and a side view schematically illustrating a configuration of a cleaning device;

FIG. 4 is a perspective view schematically illustrating a first linear transporter of a transfer apparatus;

FIG. 5 is a perspective view schematically illustrating a configuration of a hand;

FIG. 6A is a perspective view schematically illustrating a configuration of a first seating member;

FIG. 6B is a cross-sectional view taken along the line B-B in FIG. 6A;

FIG. 6C is a cross-sectional view taken along the line C-C in FIG. 6A;

FIG. 7A is a perspective view schematically illustrating a configuration of a second seating member;

FIG. 7B is a drawing schematically illustrating grip or release of a substrate from the hand to a top ring;

FIG. 7C is a cross-sectional view taken along the line C′-C′ in FIG. 6A;

FIG. 8A is a plan view schematically illustrating a configuration of the hand;

FIG. 8B is a perspective view schematically illustrating a configuration of a guiding member;

FIG. 8C is a cross-sectional view schematically illustrating the configuration of the guiding member;

FIG. 9A is a plan view schematically illustrating a configuration of the hand;

FIG. 9B is a perspective view schematically illustrating a configuration of a positioning member;

FIG. 9C is a side view schematically illustrating the configuration of the positioning member;

FIG. 10A is a perspective view schematically illustrating configurations of the hand and a hand support;

FIG. 10B is a perspective view of enlarging the hand support part in FIG. 10A;

FIG. 11A is a perspective view schematically illustrating mounting of the hand to a supporting member;

FIG. 11B is a perspective view schematically illustrating a configuration of the hand support; and

FIG. 11C is a side view and a plan view schematically illustrating the configuration of the hand support.

### DESCRIPTION OF EMBODIMENTS

The following will describe a hand, a transfer apparatus, and a substrate processing apparatus according to one embodiment of the present invention with reference to the drawings. In the drawings described later, identical reference numerals are assigned for identical or equivalent constituent elements, and therefore such elements will not be further elaborated.

<Polishing Device>

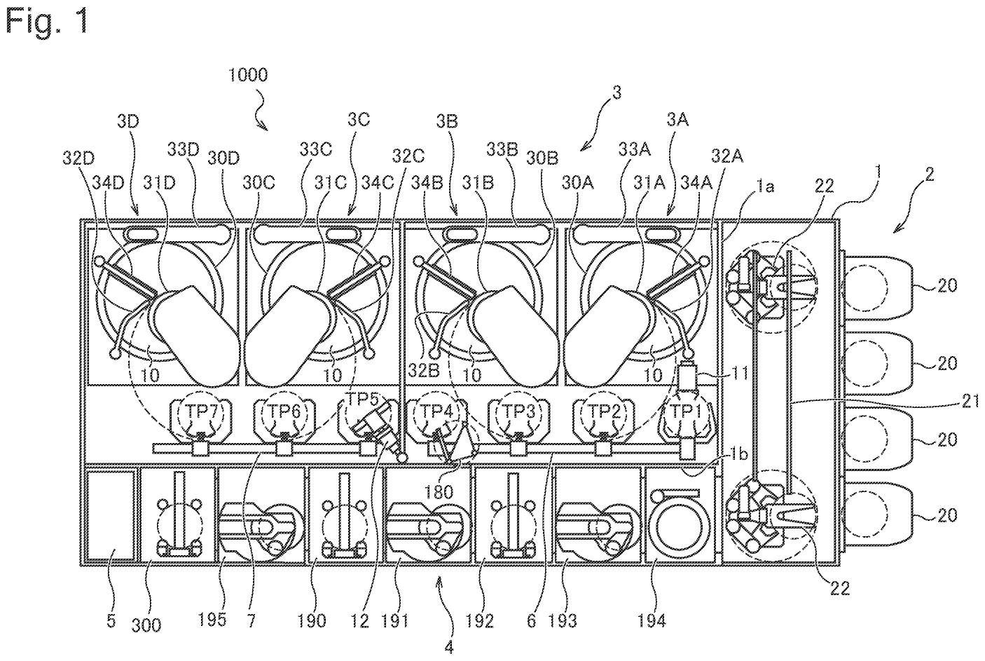

FIG. 1 is a plan view illustrating an overall configuration of a CMP apparatus as one example of a substrate processing apparatus according to one embodiment of the present invention. As illustrated in FIG. 1, a CMP apparatus 1000 includes a housing 1 having approximately a rectangular shape. The inside of the housing 1 is partitioned into a loading/unloading device 2, a polishing device 3, and a cleaning device 4 by partition walls 1a and 1b. Each of the loading/unloading device 2, the polishing device 3, and the cleaning device 4 is independently assembled and independently exhausts air. The cleaning device 4 includes a power source supply member that supplies the polishing device with a power source and a control device 5 that controls a processing operation.

<Loading/Unloading Device>

The loading/unloading device 2 includes two or more (four in this embodiment) front loading members 20 on which substrate cassettes that stock many process targets (such as circular-plate shaped substrates (wafers)) are placed. The front loading members 20 are disposed adjacent to the housing 1 and arrayed along a width direction (a direction perpendicular to a longitudinal direction) of the polishing device. On the front loading member 20, an open cassette, a Standard Manufacturing Interface (SMIF) pod or a Front Opening Unified Pod (FOUP) can be mounted. Here, the SMIF and the FOUP are sealing containers that internally house the substrate cassettes and cover them with partition walls to ensure maintaining an environment independent from an external space.

Additionally, on the loading/unloading device 2, a running mechanism 21 is laid along the arrangement of the front loading members 20. On the running mechanism 21, two transfer robots (a loader and a transfer mechanism) 22 that are movable along the array direction of the substrate cassettes are installed. The transfer robot 22 moves on the running mechanism 21 to ensure accessing the substrate cassette mounted on the front loading member 20. Each of the transfer robots 22 includes two hands on the top and bottom. The upper hand is used to return the processed substrate to the substrate cassette. The lower hand is used to take out the substrate before being processed from the substrate cassette. Thus, the upper and lower hands can be used differently. Furthermore, the lower hand of the transfer robot 22 is configured to ensure inverting the substrate.

<Polishing Device>

The polishing device 3 is a device to polish (planarize) the substrate. The polishing device 3 includes a first polishing device 3A, a second polishing device 3B, a third polishing device 3C, and a fourth polishing device 3D. As illustrated in FIG. 1, the first polishing device 3A, the second polishing device 3B, the third polishing device 3C, and the fourth polishing device 3D are arrayed along the longitudinal direction of the polishing device.

As illustrated in FIG. 1, the first polishing device 3A includes a polishing table 30A, a top ring 31A, a polishing liquid supply nozzle 32A, a dresser 33A, and an atomizer 34A. A polishing pad (a polishing tool) 10 having a polishing surface is mounted on the polishing table 30A. The top ring 31A is for holding the substrate and polishing the substrate while pressing the substrate against the polishing pad 10 on the polishing table 30A. The polishing liquid supply nozzle 32A is for supplying polishing liquid and dressing liquid (such as pure water) to the polishing pad 10. The dresser 33A is for dressing the polishing surface of the polishing pad 10. The atomizer 34A injects a mixture fluid of liquid (such as pure water) and a gas (such as nitrogen gas) or liquid (such as pure water) to remove a slurry and a polishing product and a polishing pad residue by dressing on the polishing surface.

Similarly, the second polishing device 3B includes a polishing table 30B, a top ring 31B, a polishing liquid supply nozzle 32B, a dresser 33B, and an atomizer 34B. The third polishing device 3C includes a polishing table 30C, a top ring 31C, a polishing liquid supply nozzle 32C, a dresser 33C, and an atomizer 34C. The fourth polishing device 3D includes a polishing table 30D, a top ring 31D, a polishing liquid supply nozzle 32D, a dresser 33D, and an atomizer 34D.

Since the first polishing device 3A, the second polishing device 3B, the third polishing device 3C, and the fourth polishing device 3D have the configurations identical to one another, the following will describe only the first polishing device 3A.

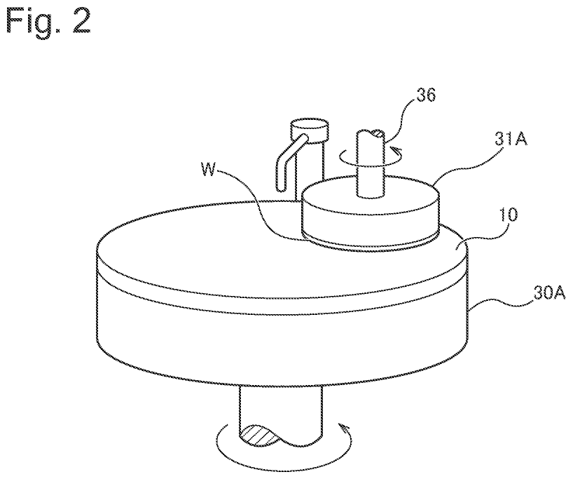

FIG. 2 is a perspective view schematically illustrating the first polishing device 3A. The top ring 31A is supported to a top ring shaft 36. The polishing pad 10 is stuck to the top surface of the polishing table 30A. The top surface of the polishing pad 10 forms the polishing surface that polishes a substrate W. Note that fixed abrasive grains can be used instead of the polishing pad 10. As indicated by the arrow, the top ring 31A and the polishing table 30A are configured to rotate about their axial centers. The substrate W is held to the lower surface of the top ring 31A by vacuum suction. During polishing, in a state where polishing liquid is supplied from the polishing liquid supply nozzle 32A to the polishing surface of the polishing pad 10, the substrate W as the polished target is pressed to the polishing surface of the polishing pad 10 by the top ring 31A to be polished.

<Cleaning Device>

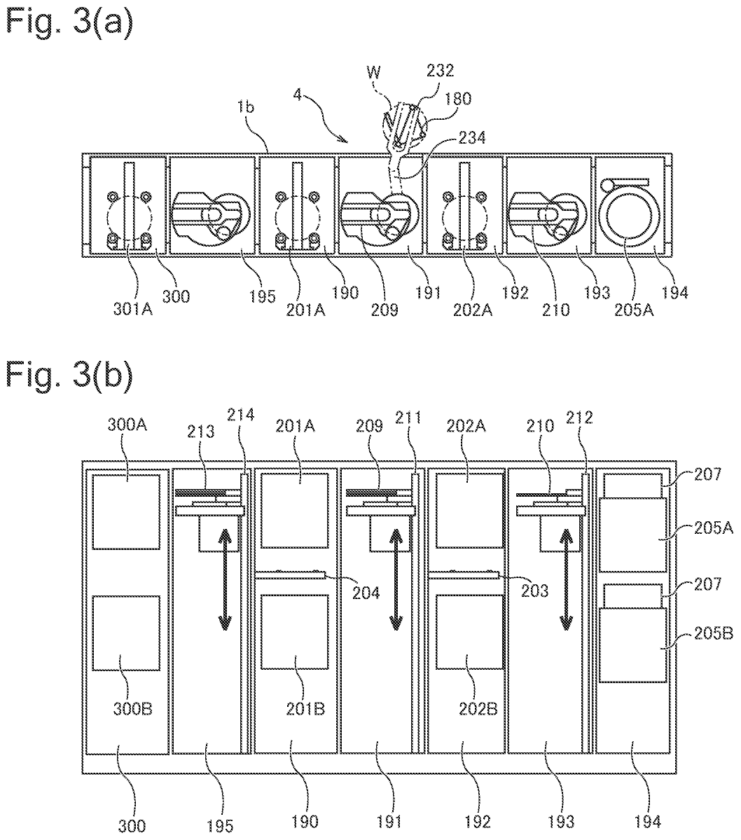

FIG. 3(a) and FIG. 3(b) are a plan view and a side view schematically illustrating a configuration of the cleaning device. FIG. 3(a) is a plan view illustrating the cleaning device 4, and FIG. 3(b) is a side view illustrating the cleaning device 4. As illustrated in FIG. 3(a) and FIG. 3(b), the cleaning device 4 includes roll cleaning chambers 190 and 300, a first transfer chamber 191, a pen cleaning chamber 192, a second transfer chamber 193, a drying chamber 194, and a third transfer chamber 195.

In the roll cleaning chamber 190, an upper roll cleaning module 201A and a lower roll cleaning module 201B arrayed along the vertical direction are disposed. The upper roll cleaning module 201A and the lower roll cleaning module 201B are cleaning machines that press two rotating roll sponges against respective front and back surfaces of the substrate while supplying the cleaning liquid to the front and back surfaces of the substrate to clean the substrate. Between the upper roll cleaning module 201A and the lower roll cleaning module 201B, a temporary placement table 204 of the substrate is disposed. In the roll cleaning chamber 300, an upper roll cleaning module 300A and a lower roll cleaning module 300B similar to the upper roll cleaning module 201A and the lower roll cleaning module 201B disposed in the roll cleaning chamber 190 are disposed.

In the pen cleaning chamber 192, an upper pen cleaning module 202A and a lower pen cleaning module 202B arrayed along the vertical direction are disposed. The upper pen cleaning module 202A and the lower pen cleaning module 202B are cleaning machines that press rotating pen sponges against the surface of the substrate and swing in a radial direction of the substrate while supplying cleaning liquid to the surface of the substrate to clean the substrate. Between the upper pen cleaning module 202A and the lower pen cleaning module 202B, a temporary placement table 203 of the substrate is disposed. Note that at a side of the first transfer chamber 191, a temporary placement table 180 of the substrate W installed to a frame (not illustrated) is disposed.

In the drying chamber 194, an upper drying module 205A and a lower drying module 205B arrayed along the vertical direction are disposed. Filter fan devices 207A and 207B that supply clean air to the insides of the respective drying modules 205A and 205B are disposed on the upper portions of the upper drying module 205A and the lower drying module 205B.

In the first transfer chamber 191, a first transfer apparatus 209 movable in the vertical direction is disposed. In the second transfer chamber 193, a second transfer apparatus 210 movable in the vertical direction is disposed. In the third transfer chamber 195, a third transfer apparatus 213 movable in the vertical direction is disposed. The first transfer apparatus 209, the second transfer apparatus 210, and the third transfer apparatus 213 are movably supported to support shafts 211, 212, and 214 extending in the vertical direction, respectively. The first transfer apparatus 209, the second transfer apparatus 210, and the third transfer apparatus 213 internally include up and down driving mechanisms, such as motors, and are movable in the vertical direction along the support shafts 211, 212, and 214. Similarly to the transfer robot 22, the first transfer apparatus 209 has two-staged hands up and down. As indicated by the dotted line in FIG. 3(a), the first transfer apparatus 209 has the lower hand disposed at a position accessible to the above-described temporary placement table 180. When the lower hand of the first transfer apparatus 209 accesses the temporary placement table 180, a shutter (not illustrated) disposed in the partition wall 1b opens.

The first transfer apparatus 209 operates so as to transfer the substrate W between the temporary placement table 180, the upper roll cleaning module 201A, the lower roll cleaning module 201B, the temporary placement table 204, the temporary placement table 203, the upper pen cleaning module 202A, and the lower pen cleaning module 202B. The first transfer apparatus 209 uses the lower hand to transfer the substrate before cleaning (the substrate to which a slurry is attached) and uses the upper hand to transfer the substrate after cleaning.

The second transfer apparatus 210 operates as to transfer the substrate W between the upper pen cleaning module 202A, the lower pen cleaning module 202B, the temporary placement table 203, the upper drying module 205A, and the lower drying module 205B. Since the second transfer apparatus 210 transfers only the cleaned substrate, the second transfer apparatus 210 includes only one hand. The transfer robot 22 illustrated in FIG. 1 uses the upper hand to take out the substrate from the upper drying module 205A or the lower drying module 205B and returns the substrate to the substrate cassette. When the upper hand of the transfer robot 22 accesses the drying module 205A or 205B, a shutter (not illustrated) disposed in the partition wall 1a opens.

The third transfer apparatus 213 operates so as to transfer the substrate W between the upper roll cleaning module 300A, the lower roll cleaning module 300B, and the temporary placement table 204. The third transfer apparatus 213 uses the lower hand to transfer the substrate before cleaning (the substrate to which the slurry is attached) and uses the upper hand to transfer the substrate after cleaning.

<Transfer Apparatus>

Next, the transfer apparatus for transferring the substrate will be described. As illustrated in FIG. 1, a first linear transporter (a transfer apparatus) 6 is disposed adjacent to the first polishing device 3A and the second polishing device 3B. The first linear transporter 6 is a device that transfers the substrate between four transfer positions along the direction in which the polishing devices 3A and 3B are arrayed (a first transfer position TP1, a second transfer position TP2, a third transfer position TP3, and a fourth transfer position TP4 in the order from the loading/unloading device side).

Additionally, a second linear transporter (a transfer apparatus) 7 is disposed adjacent to the third polishing device 3C and the fourth polishing device 3D. The second linear transporter 7 is a device that transfers the substrate between three transfer positions along the direction in which the polishing devices 3C and 3D are arrayed (a fifth transfer position TP5, a sixth transfer position TP6, and a seventh transfer position TP7 in the order from the loading/unloading device side).

The substrate is transferred to the polishing devices 3A and 3B by the first linear transporter 6. The top ring 31A of the first polishing device 3A moves between the polishing position and the second transfer position TP2 by a swing operation of a top ring head. Accordingly, grip or release of the substrate to the top ring 31A is performed at the second transfer position TP2. Similarly, the top ring 31B of the second polishing device 3B moves between the polishing position and the third transfer position TP3 and grip or release of the substrate to the top ring 31B is performed at the third transfer position TP3. The top ring 31C of the third polishing device 3C moves between the polishing position and the sixth transfer position TP6 and grip or release of the substrate to the top ring 31C is performed at the sixth transfer position TP6. The top ring 31D of the fourth polishing device 3D moves between the polishing position and the seventh transfer position TP7 and grip or release of the substrate to the top ring 31D is performed at the seventh transfer position TP7.

At the first transfer position TP1, a lifter 11 for receiving the substrate from the transfer robot 22 is disposed. The substrate is passed from the transfer robot 22 to the first linear transporter 6 via the lifter 11. The shutter (not illustrated) is disposed in the partition wall 1a positioned between the lifter 11 and the transfer robot 22, and the shutter is opened at the transfer of the substrate such that the substrate is passed from the transfer robot 22 to the lifter 11. Additionally, a swing transporter 12 is disposed between the first linear transporter 6, the second linear transporter 7, and the cleaning device 4. The swing transporter 12 has a hand movable between the fourth transfer position TP4 and the fifth transfer position TP5. The swing transporter 12 grips or releases the substrate from the first linear transporter 6 to the second linear transporter 7. The second linear transporter 7 transfers the substrate to the third polishing device 3C and/or the fourth polishing device 3D. Additionally, the substrate polished by the polishing device 3 is transferred to the cleaning device 4 via the swing transporter 12.

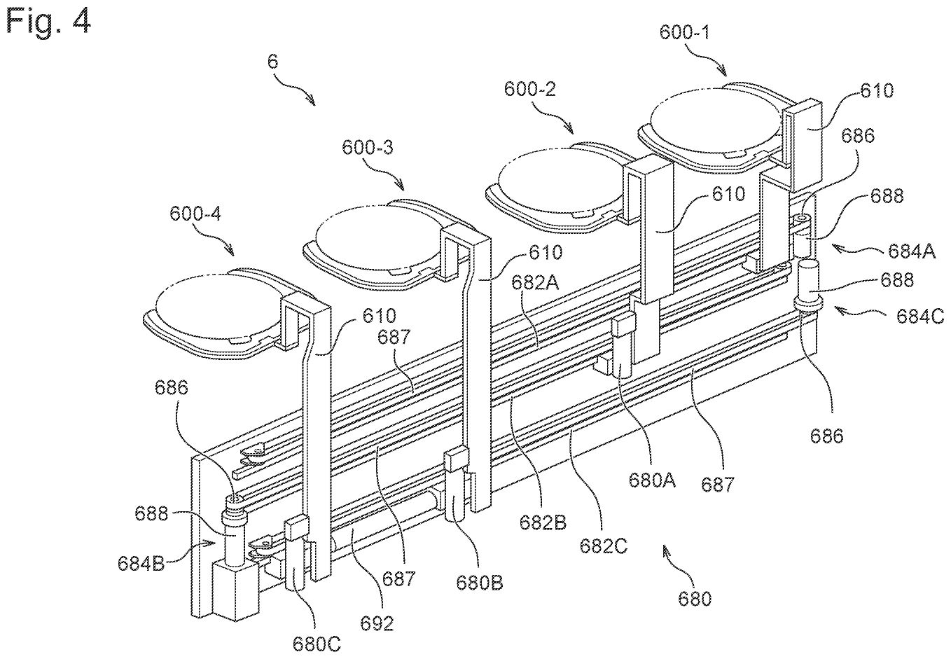

FIG. 4 is a perspective view schematically illustrating the first linear transporter 6. The first linear transporter 6 includes first, second, third, and fourth hands 600-1, 600-2, 600-3, and 600-4 for holding the substrate. The first linear transporter 6 includes supporting members 610 for supporting the respective first to fourth hands 600-1 to 600-4. The first linear transporter 6 includes a driving mechanism 680 for moving the first to fourth hands 600-1 to 600-4 via the supporting members 610. The driving mechanism 680 includes three up and down driving mechanisms (for example, motor-driven mechanisms using ball screws or air cylinders) 680A, 680B, and 680C that move the respective second, third, and fourth hands 600-2, 600-3, and 600-4 in the vertical direction, three linear guides 682A, 682B, and 682C that movably support the first to fourth hands 600-1 to 600-4 in the horizontal direction, and three horizontal driving mechanisms 684A, 684B, and 684C that drive the first to fourth hands 600-1 to 600-4 in the horizontal direction. In this embodiment, each of the horizontal driving mechanisms 684A, 684B, and 684C includes a pair of pulleys 686, a belt 687 hung on to the pulleys 686, and a servo motor 688 that rotates any one of the pair of pulleys.

The first hand 600-1 is supported to the first linear guide 682A, driven by the first horizontal driving mechanism 684A, and moves between the first transfer position TP1 and the fourth transfer position TP4. The first hand 600-1 is a path hand for receiving the substrate from the lifter 11 and passing it to the second linear transporter 7. Accordingly, when the substrate is not polished by the first polishing device 3A or the second polishing device 3B but polished by the third polishing device 3C and the fourth polishing device 3D, the first hand 600-1 is used. The first hand 600-1 does not include the up and down driving mechanism and is movable only in the horizontal direction.

The second hand 600-2 is supported to the second linear guide 682B, is driven by the second horizontal driving mechanism 684B, and moves between the first transfer position TP1 and the second transfer position TP2. The second hand 600-2 functions as an access hand for transferring the substrate from the lifter 11 to the first polishing device 3A. That is, the second hand 600-2 moves to the first transfer position TP1 and receives the substrate from the lifter 11 here. Then, the second hand 600-2 moves to the second transfer position TP2 again and passes the substrate held to the second hand 600-2 to the top ring 31A here. A first up and down driving mechanism 680A is coupled to the second hand 600-2, and they integrally move in the horizontal direction. When the substrate is passed to the top ring 31A, the second hand 600-2 is driven by the first up and down driving mechanism 680A to move up, and after passing the substrate to the top ring 31A, the second hand 600-2 is driven by the first up and down driving mechanism 680A to move down.

The third hand 600-3 and the fourth hand 600-4 are supported to the third linear guide 682C. The third hand 600-3 and the fourth hand 600-4 are coupled to one another by an air cylinder 692, are driven by the third horizontal driving mechanism 684C, and integrally move in the horizontal direction. The air cylinder 692 functions as an interval adjustment mechanism that adjusts an interval between the third hand 600-3 and the fourth hand 600-4. The reason that the air cylinder (the interval adjustment mechanism) 692 is disposed is that there may be a case where the interval between the first transfer position TP1 and the second transfer position TP2 is different from the interval between the second transfer position TP2 and the third transfer position TP3. The air cylinder 692 can perform the interval adjustment operation while the third hand 600-3 and the fourth hand 600-4 move.

The second up and down driving mechanism 680B is coupled to the third hand 600-3, the third up and down driving mechanism 680C is coupled to the fourth hand 600-4, and the third hand 600-3 and the fourth hand 600-4 are independently liftable. The third hand 600-3 moves between the first transfer position TP1, the second transfer position TP2, and the third transfer position TP3, and simultaneously the fourth hand 600-4 moves between the second transfer position TP2, the third transfer position TP3, and the fourth transfer position TP4.

The third hand 600-3 functions as an access hand for transferring the substrate from the lifter 11 to the second polishing device 3B. That is, the third hand 600-3 moves to the first transfer position TP1, receives the substrate from the lifter 11 here, further moves to the third transfer position TP3, and operates to pass the substrate to the top ring 31B. The third hand 600-3 also functions as an access hand for transferring the substrate polished in the first polishing device 3A to the second polishing device 3B. That is, the third hand 600-3 moves to the second transfer position TP2, receives the substrate from the top ring 31A here, further moves to the third transfer position TP3, and operates to pass the substrate to the top ring 31B. When the substrate is gripped or released between the third hand 600-3 and the top ring 31A or the top ring 31B, the third hand 600-3 is driven by the second up and down driving mechanism 680B to move up and after the third hand 600-3 finishes gripping or releasing the substrate, the third hand 600-3 is driven by the second up and down driving mechanism 680B to move down.

The fourth hand 600-4 functions as an access hand for transferring the substrate polished by the first polishing device 3A or the second polishing device 3B to the swing transporter 12. That is, the fourth hand 600-4 moves to the second transfer position TP2 or the third transfer position TP3, receives the polished substrate from the top ring 31A or the top ring 31B here, and thereafter moves to the fourth transfer position TP4. When the fourth hand 600-4 receives the substrate from the top ring 31A or the top ring 31B, the fourth hand 600-4 is driven by the third up and down driving mechanism 680C to move up, and after receiving the substrate, the fourth hand 600-4 is driven by the third up and down driving mechanism 680C to move down.

The second linear transporter 7 differs from the first linear transporter 6 in that the component equivalent to the first hand 600-1 is not provided, but otherwise has the configuration basically identical to the first linear transporter 6 and therefore the detailed description will be omitted.

<Hand>

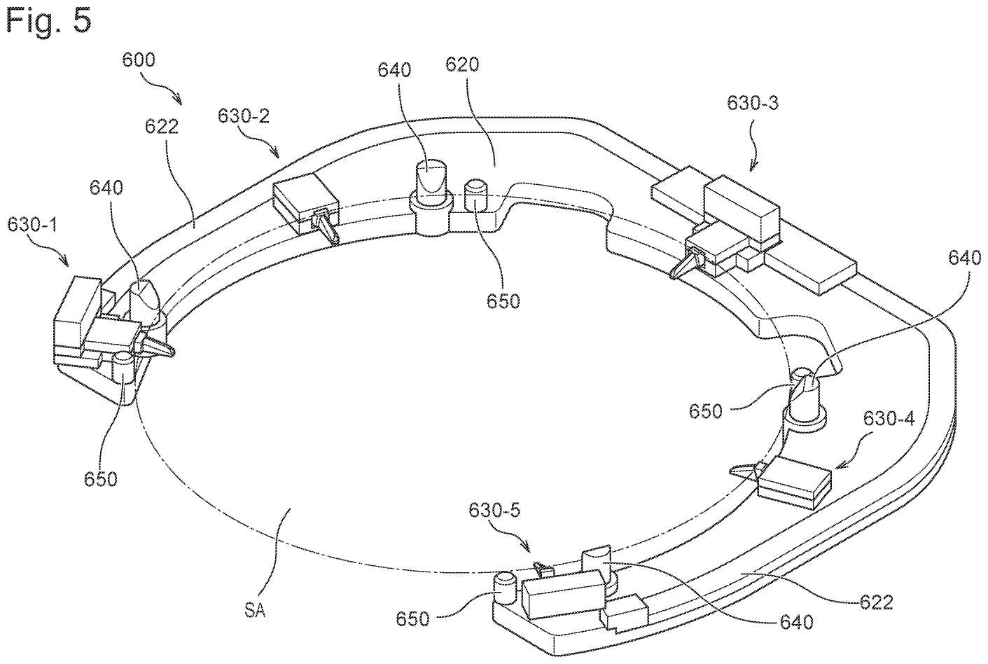

Next, details of the hand will be described. The first to fourth hands 600-1 to 600-4 have the similar configurations, and therefore only the description of one hand (for convenience, referred to as a “hand 600”) will be given. FIG. 5 is a perspective view schematically illustrating a configuration of the hand.

As illustrated in FIG. 5, the hand 600 includes a hand main body 620 and a plurality of (five in this embodiment) seating members 630-1 to 630-5 mounted on the hand main body 620. The hand main body 620 is a plate-shaped member formed in an approximately U-shape so as to surround a seating region SA of the substrate. The seating members 630-1 to 630-5 are members on which the substrate is to be seated. The seating members 630-1 to 630-5 are mounted on the hand main body 620 at intervals from one another so as to surround the seating region SA. Note that an example in which the hand 600 includes the five seating members 630-1 to 630-5 is described in this embodiment, but the number of the seating members 630 is arbitrary. The hand 600 only needs to include three or more of the seating members 630 that allow holding the substrate W horizontally as much as possible and equally distributing the weight of the substrate W.

The types of the seating members 630-1 to 630-5 are divided into two depending on presence of seating sensors for detecting the seating of the substrate on the hand 600. In this embodiment, whereas the seating members 630-1, 630-3, and 630-5 include the seating sensors, the seating members 630-2 and 630-4 do not include the seating sensors. Hereinafter, for discrimination of both, the seating members 630-1, 630-3, and 630-5 will be appropriately referred to as “first seating members” and the seating members 630-2 and 630-4 will be referred to as “second seating members.”

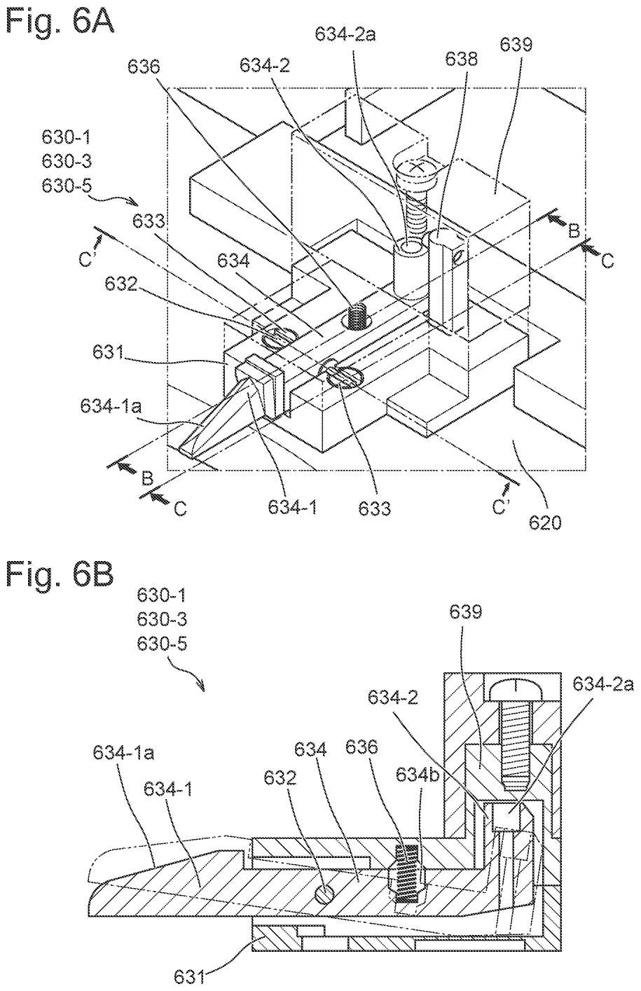

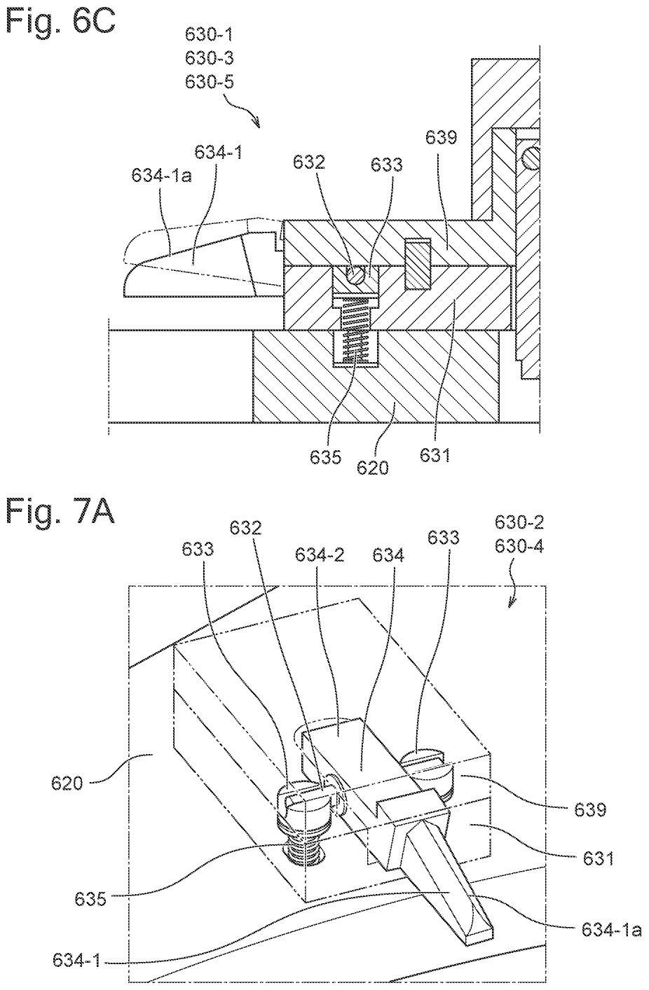

FIG. 6A is a perspective view schematically illustrating the configuration of the first seating member. FIG. 6B is a cross-sectional view taken along the line B-B in FIG. 6A. FIG. 6C is a cross-sectional view taken along the line C-C in FIG. 6A. As illustrated in FIG. 6A to FIG. 6C, each of the first seating members 630-1, 630-3, and 630-5 includes a pedestal 631 mounted on the hand main body 620, a shaft member 632 supported to the hand main body 620 via the pedestal 631, and a lever member 634 supported to the shaft member 632. The lever member 634 is a rod-shaped member disposed in a groove formed in the pedestal 631. The lever member 634 includes a first end portion 634-1 including a seating portion 634-1a on which the substrate is to be seated and a second end portion 634-2 disposed on the side opposite to the first end portion 634-1 across the shaft member 632. The lever member 634 is supported to the shaft member 632 such that the first end portion 634-1 projects to the seating region SA.

Additionally, each of the first seating members 630-1, 630-3, and 630-5 includes a biasing member 636 for giving a force to rotate the lever member 634 to the lever member 634. The biasing member 636 gives the force to rotate the lever member 634 to the lever member 634 such that the second end portion 634-2 moves downward. Accordingly, as indicated by the dashed line in FIG. 6B, while the substrate is not seated on the lever member 634, the second end portion 634-2 moves downward. The biasing member 636 is a compression spring in this embodiment. Specifically, the compression spring has one end mounted on a housing 639 that covers the upper portion of the lever member 634 and the other end mounted on a bottom surface of a hole 634b, which is formed in the top surface on the second end portion 634-2 side with respect to the shaft member 632 of the lever member 634. Note that the biasing member 636 is not limited to the compression spring, only needs to give the above-described biasing force to the lever member 634 and is applicable as long as being an elastic body, such as a rubber.

Each of the first seating members 630-1, 630-3, and 630-5 further includes a seating sensor 638 for detecting seating of the substrate on the hand 600. Specifically, the seating sensor 638 is configured to detect upward movement of the second end portion 634-2. That is, in FIG. 6B, while the substrate is not seated on the lever member 634, as indicated by the dashed line, by biasing the lever member 634 by the biasing member 636, the second end portion 634-2 is positioned downward. On the other hand, when the substrate is seated on the seating portion 634-1a of the lever member 634, due to the weight of the substrate, the lever member 634 rotates about the shaft member 632, the first end portion 634-1 moves downward, and the second end portion 634-2 moves upward. A magnet 634-2a is disposed on the second end portion 634-2 of the lever member 634. The seating sensor 638 includes a magnetic sensor that detects the upward movement of the magnet 634-2a. When the magnet 634-2a moves upward to approach the magnetic sensor, the seating sensor 638 detects the change in magnetic reluctance and thus detects the upward movement of the second end portion 634-2 and, in other words, the substrate being seated on the seating portion 634-1a of the lever member 634.

Note that the hand main body 620 includes a wiring cover 622 along the outer shape of the hand main body 620. A cable connected to the seating sensor 638 is wired through the inside of the wiring cover 622. Additionally, the first seating members 630-1, 630-3, and 630-5 include the housings 639 configured to cover the second end portions 634-2 of the lever members 634 and the seating sensors 638.

According to this embodiment, the accuracy of seating detection of the substrate can be improved. That is, in the related art, the seating detection was performed using the optical sensor disposed in the seating portion 634-1a. Here, since the seating portion 634-1a was at the position projected to the seating region SA and cleaning water used for the cleaning process and a slurry used for the polishing process were mixed in the seating region SA, light of the optical sensor was diffusely reflected by the cleaning water or the slurry, and this resulted in false detection of substrate seating in some cases. In contrast to this, in this embodiment, the seating sensor 638 is configured to perform seating detection by detection of the upward movement of the second end portion 634-2. The second end portion 634-2 is on the side opposite to the first end portion 634-1 including the seating portion 634-1a across the shaft member 632 and is away from the seating region SA, and therefore the second end portion 634-2 is less likely to receive disturbance by the cleaning water or the slurry, and consequently, the accuracy of seating detection of the substrate can be improved. Additionally, in this embodiment, since the housing 639 covers the second end portion 634-2 and the seating sensor 638, disturbance by the cleaning water or the slurry is further less likely to be received, and consequently, the accuracy of seating detection of the substrate can be improved.

Note that, in this embodiment, an example in which the seating sensor 638 includes an auto switch sensor that detects the magnet 634-2a disposed on the second end portion 634-2 by the magnetic sensor has been described, but the configuration is not limited to this. For example, the seating sensor 638 may include an optical sensor that includes a light projecting component and a light receiving component. In this case, the light projecting component and the light receiving component are disposed at the proximity of the second end portion 634-2. The lever member 634 is supported to the shaft member 632 such that the second end portion 634-2 blocks between the light projecting component and the light receiving component when the second end portion 634-2 moves upward. Thus, while the substrate is not seated on the lever member 634, the second end portion 634-2 is positioned downward, and the light receiving component can detect the light output from the light projecting component. On the other hand, when the second end portion 634-2 moves upward, the light receiving component cannot detect the light output from the light projecting component, and thus seating of the substrate on the lever member 634 can be detected.

In this embodiment, the seating is determined by the movement of the magnet 634-2a between the positions of the two-dot chain line and the solid line in FIG. 6B. In this embodiment, the position of the seating sensor 638 is disposed on the lateral side (the side surface) of the second end portion 634-2, but may be disposed at a position of a lower surface of a bolt of the housing 639 where the seating sensor 638 faces the top surface of the magnet 634-2a. Additionally, the seating sensor 638 may include an electric sensor. In this case, a first electric contact is disposed on the second end portion 634-2 of the lever member 634. The seating sensor 638 includes a second electric contact in contact with the first electric contact when the second end portion 634-2 moves upward, and the seating of the substrate on the lever member 634 can be detected through the change in voltage. Additionally, the seating sensor 638 may include a piezoelectric sensor (a pressure sensor) or a strain gauge sensor. In this case, the piezoelectric sensor (the pressure sensor) or the strain gauge sensor is installed on the contact portion at the distal end or the end portion of the second end portion 634-2 and the change in pressure or the change in strain is detected, thus ensuring detecting the seating of the substrate on the lever member 634. The seating member described in this embodiment is applicable to not only a mobile hand but also is applicable to a temporary placement table of the substrate in the middle of transfer and a positioning table that matches orientations of notches and orientation flats.

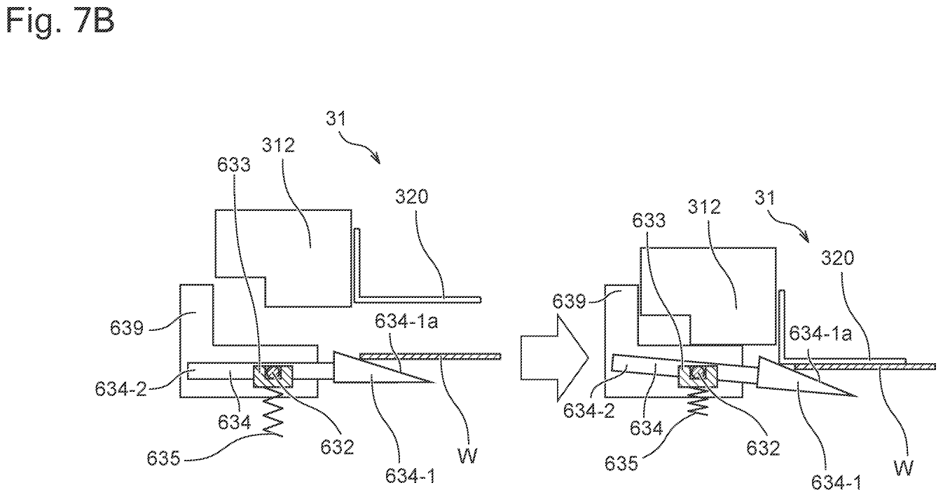

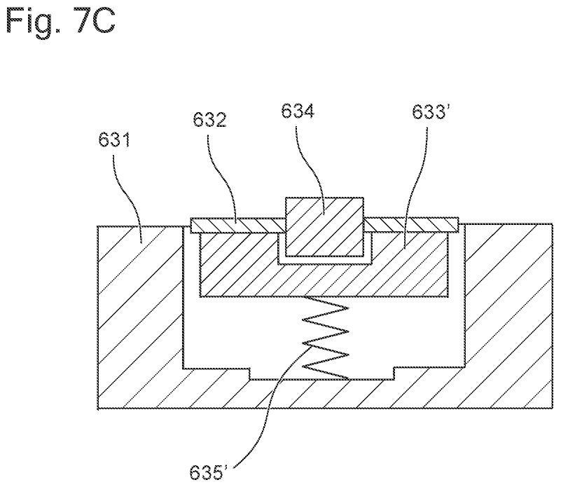

FIG. 7A is a perspective view schematically illustrating the configuration of the second seating member. The second seating members 630-2 and 630-4 differ from the first seating members 630-1, 630-3, and 630-5, in that the biasing members 636 or the seating sensors 638 are not provided. Since the other components have the similar functions, the similar reference numerals are assigned for the components having the similar functions. As illustrated in FIG. 7A, each of the second seating members 630-2 and 630-4 includes the pedestal 631 mounted on the hand main body 620, the shaft member 632 supported to the hand main body 620 via the pedestal 631, and the lever member 634 supported to the shaft member 632. The lever member 634 includes the first end portion 634-1 including the seating portion 634-1a on which the substrate is to be seated and the second end portion 634-2 disposed on the side opposite to the first end portion 634-1 across the shaft member 632. The lever member 634 is supported to the shaft member 632 such that the first end portion 634-1 projects to the seating region SA. The lever member 634 and the shaft member 632 are covered with the housing 639.

Additionally, as illustrated in FIG. 6A, FIG. 6C, and FIG. 7A, each of the seating members 630-1 to 630-5 includes a pair of bearings 633 for supporting both end portions of the shaft member 632 and a pair of elastic members 635 for supporting the pair of bearings 633. The elastic member 635 is a spring member in this embodiment. The spring member has one end mounted on the lower surface of the bearing 633 and the other end mounted on a bottom surface of a hole formed in the top surface of the hand main body 620. This configuration supports the lever members 634 to the hand main body 620 via the elastic members 635. Note that the elastic member 635 is not limited to the spring member and only needs to be a member that allows absorbing the pressing load from the top ring.

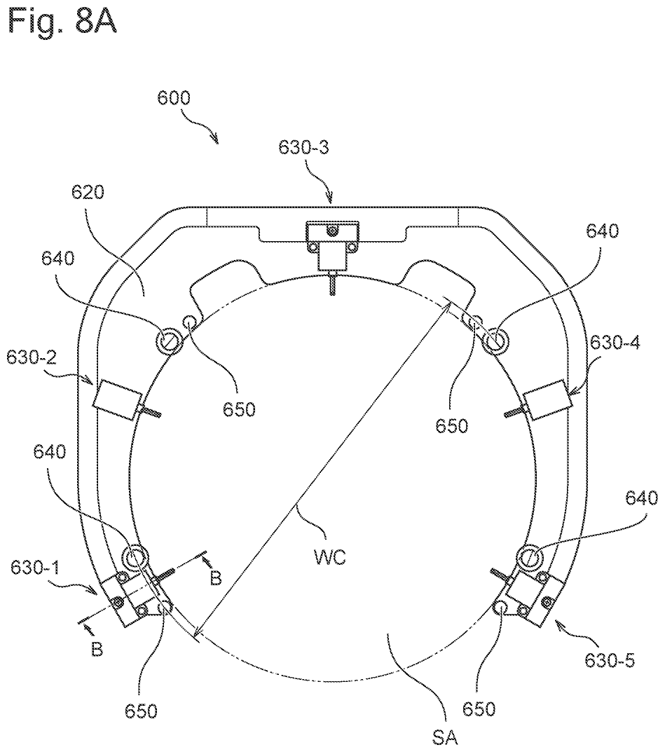

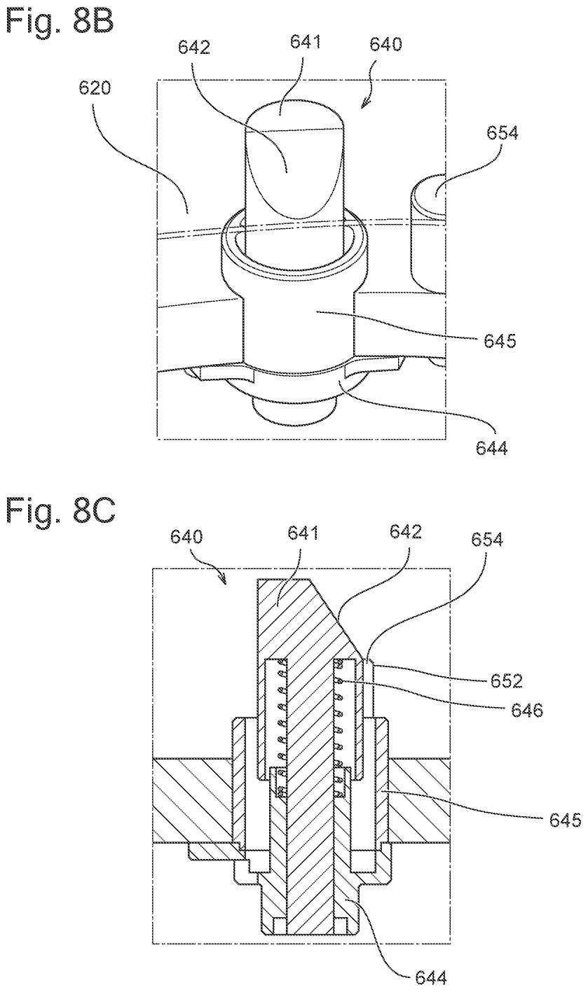

FIG. 7B is a drawing schematically illustrating the grip or release of the substrate from the hand to the top ring. FIG. 7B schematically illustrates the cross-sectional surface taken along the line B-B in FIG. 8A described later. A top ring 31 includes an annular retainer ring 312, a membrane 320 surrounded by the retainer ring 312, and the like. As illustrated in FIG. 7B, the housing 639 of the seating member has an L-shaped cross-sectional surface. The retainer ring 312 is disposed so as to be housed in a space surrounded by the L-shaped housing 639 when the substrate W is gripped or released from the hand 600 to the top ring 31. This allows easily confirming the positional relationship between the hand 600 and the top ring 31. Additionally, as illustrated in FIG. 7B, when the substrate W is gripped or released from the hand to the top ring 31, the membrane 320 is pressed against the substrate W for vacuum suction. In this respect, the lever member 634 on which the substrate W is to be seated is supported to the hand main body 620 via the elastic member 635. Accordingly, when the substrate W is pressed down by the membrane 320, the elastic member 635 absorbs the pressing load.

According to this embodiment, the pressing load from the top ring can be further stably absorbed. That is, in the related art, the hand included the upper and lower two blades (the upper blade and the lower blade) and absorbed the pressing load from the top ring by disposing the elastic member between the blades. In this case, when the membrane of the top ring is pressed against the substrate W, the pressing load is received by the whole upper blade. Accordingly, for example, when the membrane partially contacted the substrate W, a part of the upper blade was pressed down and the upper blade was inclined, possibly making the absorption of the pressing load unstable.

In contrast to this, in this embodiment, since each of the seating members 630-1 to 630-5 includes the elastic member 635 that supports the lever member 634, the hand main body 620 can be configured by one, and the cost can be saved. In addition, since the lever member 634 of each of the seating members 630-1 to 630-5 is supported to one hand main body 620 via the elastic member 635, for example, when the membrane 320 partially contacts the substrate W, any of the seating members 630-1 to 630-5 corresponding to the partially contacted position absorbs the pressing load, and therefore the hand main body 620 is less likely to be inclined. As a result, according to this embodiment, the pressing load from the top ring can be further stably absorbed. Note that the elastic member 635 need not be disposed in the hand (such as the first hand 600-1) that does not receive the pressing load from the top ring among the first to fourth hands 600-1 to 600-4. Additionally, the hand 600 of this embodiment supports and fixes the substrate W, and further the way of insertion and arrangement of the substrate W with respect to the supporting portion is to horizontally put the substrate W into the supporting portion. With the hand 600 in this embodiment, the hand 600 is not horizontally moved from both the side surface directions of the substrate W or gripped so as to be sandwiched.

Note that in the embodiment described above, an example in which each of the seating members 630-1 to 630-5 includes the pair of bearings 633 for supporting both the end portions of the shaft member 632 and the pair of elastic members 635 for supporting the pair of bearings 633 has been described, but the configuration is not limited to this. The following will describe a modification of the pair of bearings 633 and the pair of elastic members 635. FIG. 7C is a cross-sectional view taken along the line C′-C′ in FIG. 6A. As illustrated in FIG. 7C, each of the seating members 630-1 to 630-5 may include a bearing 633′ for supporting both the end portions of the shaft member 632. The bearing 633′ is a single member that extends across both the end portions of the shaft member 632 below the shaft member 632. Additionally, as illustrated in FIG. 7C, each of the seating members 630-1 to 630-5 may include a single elastic member 635′ that supports the center of the lower surface of the bearing 633′.

According to this modification, similarly to the embodiment described above, the lever member 634 of each of the seating members 630-1 to 630-5 is supported to one hand main body 620 via the elastic member 635′, and thus the pressing load from the top ring can be further stably absorbed.

<Guiding Member and Positioning Member>

Next, the guiding member and the positioning member disposed in the hand 600 will be described. FIG. 8A is a plan view schematically illustrating the configuration of the hand. FIG. 8B is a perspective view schematically illustrating the configuration of the guiding member. FIG. 8C is a cross-sectional view schematically illustrating the configuration of the guiding member.

As illustrated in FIG. 8A, the hand 600 includes a plurality of (four in this embodiment) guiding members 640. The plurality of guiding members 640 are mounted on the hand main body 620 at predetermined intervals with one another so as to surround the seating region SA. Each of the plurality of guiding members 640 includes a columnar guide main body 641 extending in the vertical direction and a substrate receiving surface 642 formed on the guide main body 641 so as to be inclined downward toward the seating region SA. A supporting member 644 for supporting the guide main body 641 is fixed to the lower surface of the hand main body 620. Additionally, a cylindrical member 645 is mounted on a through-hole of the hand main body 620. The guide main body 641 is inserted into the inside of the cylindrical member 645 and is supported to the supporting member 644 via an elastic member 646 (a spring member). This allows absorbing a load applied to the guide main body 641 by the elastic member 646.

By formation of the substrate receiving surface 642 on the guide main body 641, as illustrated in FIG. 8A, a substrate scooping diameter WC larger than a diameter of the seating region SA is disposed. The substrate scooping diameter WC is a diameter of a circle connecting upper ends of the substrate receiving surfaces 642 of the plurality of guide main bodies 641. Even when the substrate is passed to the outside of the seating region SA when the hand 600 receives the substrate from the top ring, as long as the substrate is within a range of the substrate scooping diameter WC, the substrate can be seated on the seating region SA. This respect will be described below together with a positioning member described below.

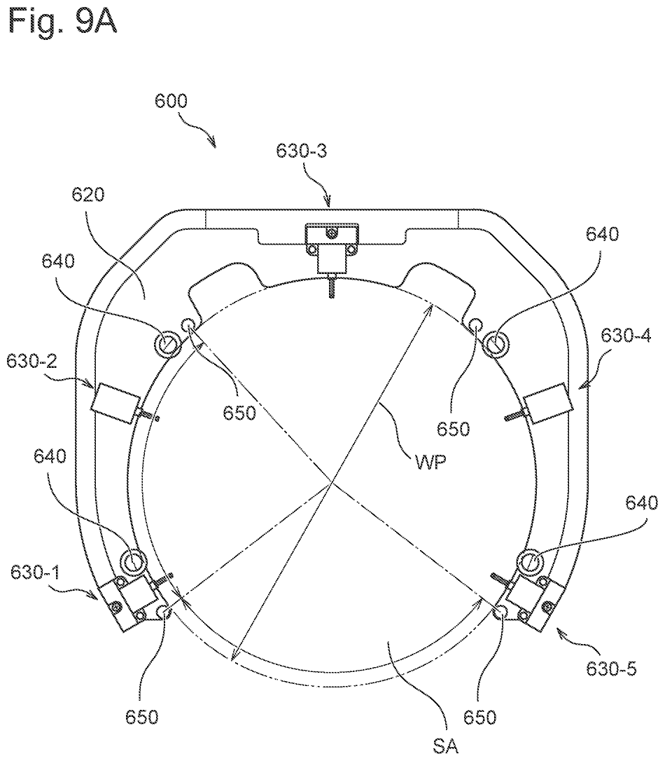

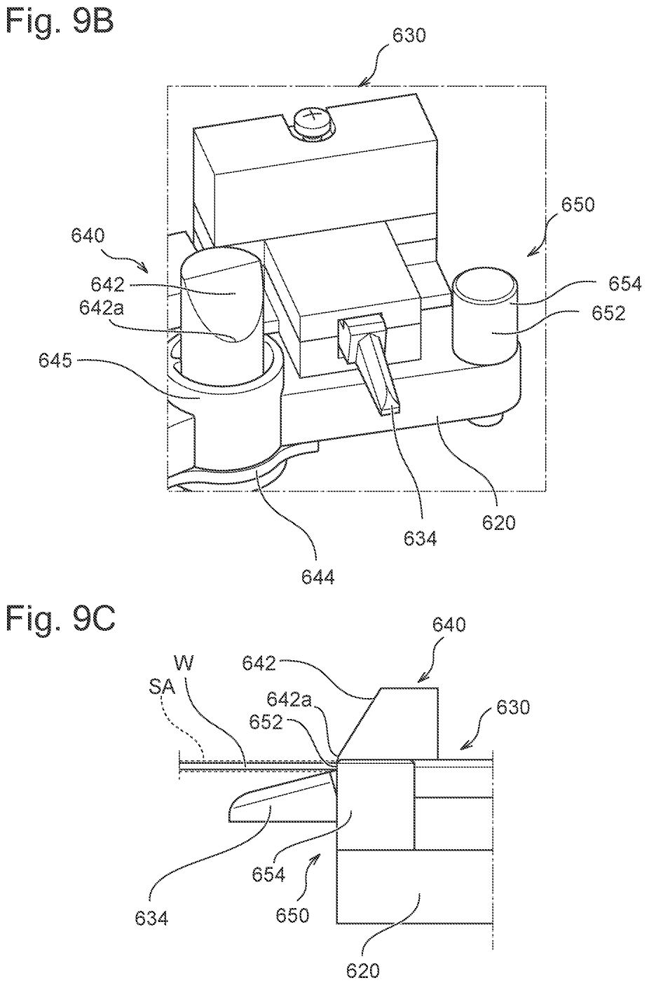

FIG. 9A is a plan view schematically illustrating the configuration of the hand. FIG. 9B is a perspective view schematically illustrating the configuration of the positioning member. FIG. 9C is a side view schematically illustrating the configuration of the positioning member. As illustrated in FIG. 9A to FIG. 9C, the hand 600 includes a plurality of (four in this embodiment) positioning members 650. The plurality of positioning members 650 are mounted on the hand main body 620 at predetermined intervals with one another so as to surround the seating region SA. Each of the plurality of positioning members 650 includes a positioning portion 652 in contact with the outer edge of the seating region SA. Specifically, each of the positioning members 650 includes a positioning post 654 formed in a columnar shape extending vertically upward from the top surface of the hand main body 620, and the positioning portion 652 is formed on a side surface in contact with the substrate W of the positioning post 654. Configuring the positioning member 650 by the positioning post 654 having the columnar shape allows reducing the contact area of the substrate and the positioning post 654, thereby ensuring reducing a defect of the substrate surface.

As illustrated in FIG. 9A, the four positioning members 650 are disposed at approximately the uniform intervals with the adjacent positioning members 650. The uniform intervals with the adjacent positioning members 650 (the four positioning members 650 are disposed at intervals of 90°) brings an effect of suppressing coming out of the substrate W from the hand 600 during transfer of the substrate W (especially transfer in the horizontal direction). In this embodiment, for convenience of the shape of the hand main body 620 (the upper limit of the dimension in the longitudinal direction of the hand main body 620), the positioning members 650 are not disposed to be perfectly uniform but are disposed appropriately uniform, and therefore the substrate W coming out from the hand 600 during transfer of the substrate W can be suppressed. Furthermore, when there is a possibility that the substrate W climbs over the positioning member 650 described below, falling of the substrate W from the opposed position of the climbing over part can be suppressed. Additionally, as illustrated in FIG. 9A, the four positioning members 650 are disposed such that a diameter (a substrate positioning diameter WP) of a circle connecting the respective positioning portions 652 has a slight margin with respect to the diameter of the substrate W. Additionally, as illustrated in FIG. 9C, a lower end 642a of the substrate receiving surface 642 is formed at a position corresponding to the outer edge of the seating region SA. A diameter of a circle connecting the positioning members 650 need to be larger than the diameter of the circle connecting the lower ends 642a of the substrate receiving surfaces 642 of the guiding members 640. Because there is a possibility that the substrate W climbs over the positioning member 650. Additionally, the positioning member 650 need to be positioned inward the inner diameter of the retainer ring 312. This is because to avoid the contact with the membrane when the substrate W is gripped or released to the top ring 31.

According to this embodiment, when the substrate W is received from the top ring 31, falling of the substrate W from the hand can be suppressed and the substrate W can be positioned at the predetermined seating region SA. That is, when the hand 600 receives the substrate W from the top ring 31, supplying a fluid to the suction surface of the substrate W suctioned by the membrane 320 of the top ring 31 separates the substrate W from the membrane 320. In this case, when the substrate W separates from the membrane 320 with a horizontal state maintained, this causes no problem. However, there may be a case where, by separating the substrate W from the membrane 320 only at one side of the substrate W, the inclined substrate W moves down to the hand 600. In the case, according to this embodiment, although the inclined one side of the substrate W that moves down moves down to the inside of the outer edge of the seating region SA, the lever members 634 of the seating members 630-1 to 630-5 project to the seating region SA, and therefore the one side of the substrate W is supported to the seating portion 634-1a of any of the lever members 634. Whereas the opposite side of the substrate W moves down subsequently, the one side is supported to the lever member 634 at the inside of the outer edge of the seating region SA, and therefore the opposite side of the substrate W is supported to the substrate receiving surfaces 642 formed on the guide main bodies 641 at the opposed position. Since the substrate receiving surfaces 642 are inclined downward toward the seating region SA, when the opposite side of the substrate W slides down the substrate receiving surfaces 642, the substrate W is seated on the seating region SA. At this time, since the plurality of positioning members 650 including the positioning portions 652 in contact with the outer edge of the seating region SA are disposed around the seating region SA, the substrate W is positioned in the seating region SA.

<Hand Support>

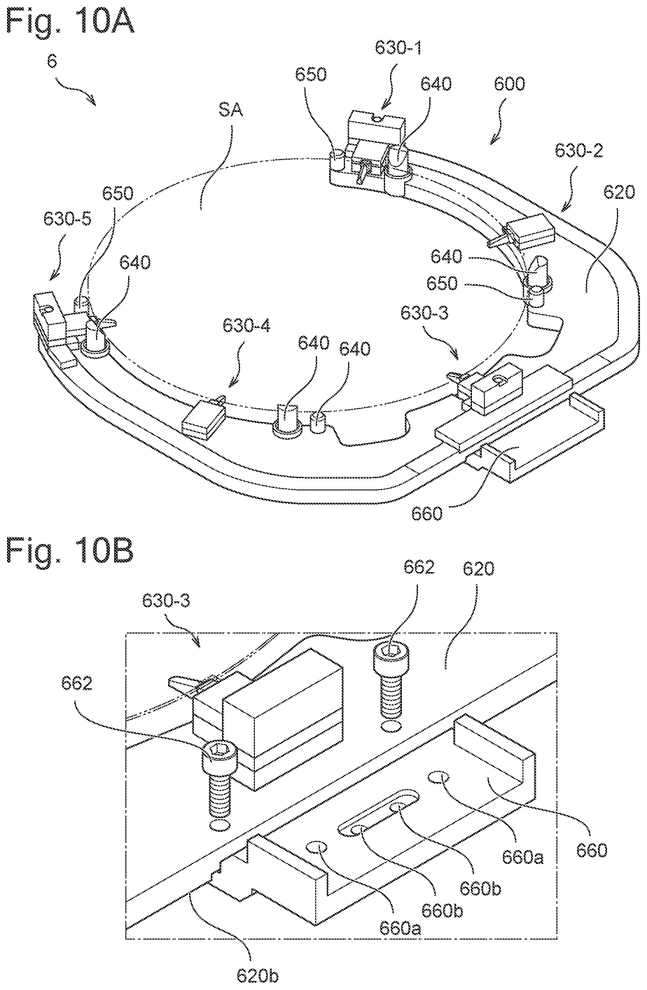

Next, a mechanism for mounting the hand 600 on the supporting member 610 will be described. FIG. 10A is a perspective view schematically illustrating configurations of the hand and the hand support. FIG. 10B is a perspective view of enlarging the hand support part in FIG. 10A. As illustrated in FIG. 10A and FIG. 10B, the first linear transporter 6 includes a hand support 660 for mounting the hand 600 on the supporting member 610 illustrated in FIG. 4. The hand support 660 is a member configured to support a lower surface 620b of the hand main body 620 and is fixed to the hand main body 620 with bolts 662. The hand support 660 has bolt holes 660a and 660b for fixing the hand support 660 to the supporting member 610. Fixing the hand support 660 and the supporting member 610 with the bolts allows mounting the hand 600 on the supporting member 610.

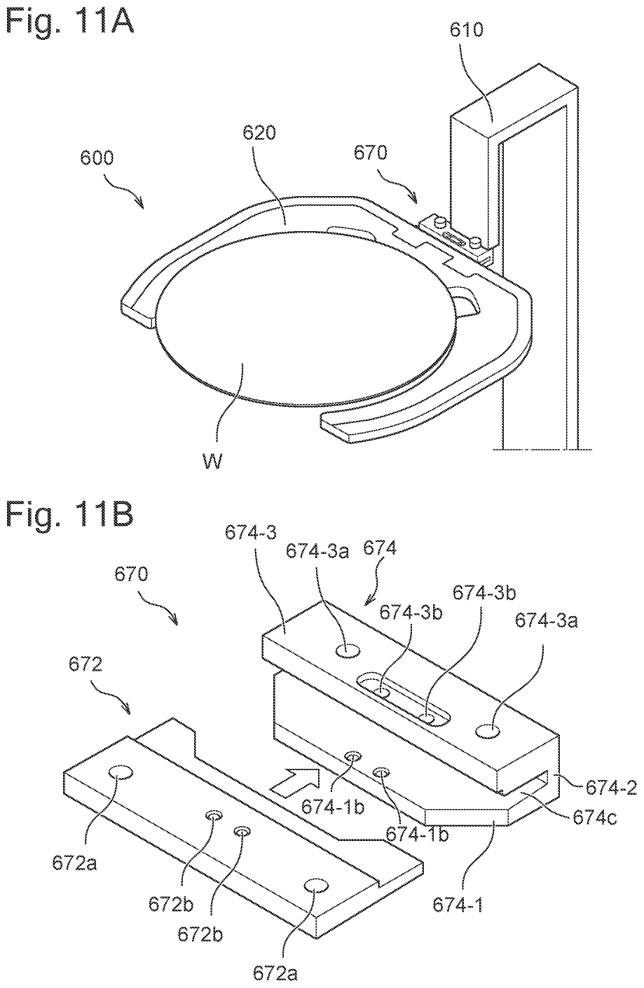

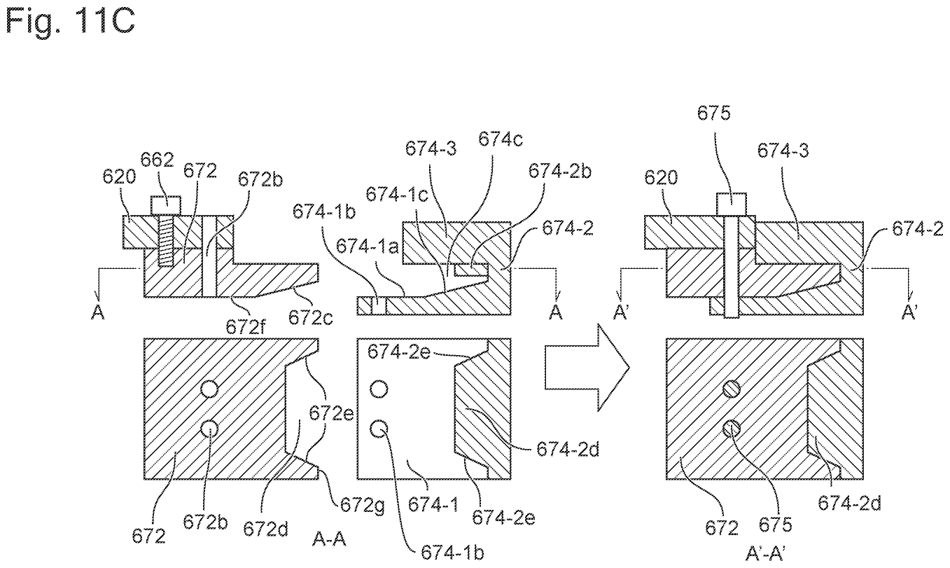

Note that, in the embodiment of FIG. 10A and FIG. 10B, an example of directly mounting the hand support 660 on the supporting member 610 has been described, but the mounting is not limited to this. The following will describe a hand support according to another embodiment. FIG. 11A is a perspective view schematically illustrating mounting of the hand to the supporting member. FIG. 11B is a perspective view schematically illustrating the configuration of the hand support. FIG. 11C is a side view and a plan view schematically illustrating the configuration of the hand support.

As illustrated in FIG. 11A to FIG. 11C, a hand support 670 includes a first hand support 672 mounted on the hand 600 and a second hand support 674 mounted on the supporting member 610. The first hand support 672 is a plate-shaped member configured to support the lower surface of the hand main body 620. The first hand support 672 has bolt holes 672a for fixing the first hand support 672 to the hand main body 620 with bolts.

The second hand support 674 includes a plate-shaped lower support 674-1 and a plate-shaped upper support 674-3 disposed at an interval and a connecting member 674-2 connecting the end portions of both and having an approximately U-shaped groove shape. Between the lower support 674-1 and the upper support 674-3, a coupling region 674c into which the first hand support 672 is inserted is formed. The upper support 674-3 has bolt holes 674-3a and 674-3b for fixing the second hand support 674 to the supporting member 610 with bolts.

As illustrated in FIG. 11C, the hand main body 620 is fixed to the first hand support 672 with a bolt 662. Additionally, the first hand support 672 has a pin hole 672b for coupling the first hand support 672 and the second hand support 674 with a pin 675. Additionally, a tapered surface 672c inclined so as to taper off toward the second hand support 674 is formed in a bottom surface 672f of the first hand support 672. Additionally, a cutout 672d having a trapezoidal shape in plan view is formed in a side surface 672g on the second hand support 674 side of the first hand support 672. In the cutout 672d, a pair of tapered surfaces 672e are formed in leg parts of the trapezoidal shape. Note that while an example in which the cutout 672d having the trapezoidal shape in plan view is formed has been described in this embodiment, the cutout 672d may have any shape.

On the other hand, the lower support 674-1 has a pin hole 674-1b for coupling the first hand support 672 and the second hand support 674 with the pin 675. Moreover, a tapered surface 674-1c inclined corresponding to the tapered surface 672c is formed in the coupling region 674c. Specifically, in a top surface 674-1a of the lower support 674-1, the tapered surface 674-1c inclined upward toward the connecting member 674-2 is formed. The tapered surface 674-1c is inclined corresponding to the tapered surface 672c.

Additionally, the coupling region 674c includes a protrusion 674-2d having tapered surfaces 674-2e inclined corresponding to the pair of tapered surfaces 672e in the leg parts of the trapezoidal shape of the cutout 672d. Specifically, the protrusion 674-2d is formed projecting from the connecting member 674-2 to the first hand support 672 side. The protrusion 674-2d has a shape corresponding to the cutout 672d and has a trapezoidal shape in plan view. In the protrusion 674-2d, a pair of the tapered surfaces 674-2e are formed in leg parts of the trapezoidal shape. Note that, in this embodiment, an example in which the cutout 672d is formed in the first hand support 672 and the protrusion 674-2d is formed in the second hand support 674 has been described, but the configuration is not limited to this. For example, a cutout may be formed in the second hand support 674, and the protrusion having the shape corresponding to the cutout may be formed in the first hand support 672.

With the hand support 670 of this embodiment, the first hand support 672 is inserted into the coupling region 674c and the first hand support 672 and the second hand support 674 are coupled with the pin 675 to ensure mounting the hand 600 on the supporting member 610.

With the hand support 670 according to this embodiment, the hand 600 can be mounted on the accurate position of the supporting member 610 in a short time. That is, since there is a concern of, for example, abrasion, the components of the hand 600, especially the seating members 630-1 to 630-5 in contact with the substrate are preferably periodically replaced. To replace the component, a work of removing the hand 600 from the supporting member 610 and mounting the hand 600 again on the supporting member 610 after the component replacement occurs. Here, for example, as illustrated in FIG. 10A and FIG. 10B, to directly mount the hand support 660 on the supporting member 610, positioning of the hand 600 is difficult and mounting at high accuracy takes time and therefore operation efficiency is poor.

In contrast to this, with the hand support 670, when the first hand support 672 is inserted into the coupling region 674c, the tapered surface 672c is guided to the tapered surface 674-1c and the pair of tapered surfaces 672e are guided to the tapered surfaces 674-2e, and therefore the first hand support 672 can be easily positioned at the accurate position inside the coupling region 674c. After the first hand support 672 is positioned at the accurate position, the positions of the pin hole 672b and the pin hole 674-1b are matched. Accordingly, inserting the pin 675 allows easily coupling the first hand support 672 and the second hand support 674 without fastening the bolt. Note that, in this embodiment, an example in which the first hand support 672 is mounted on the hand 600 and the second hand support 674 is mounted on the supporting member 610 has been described, but the configuration is not limited to this. The first hand support 672 may be mounted on the supporting member 610, and the second hand support 674 may be mounted on the hand 600.

Several embodiments of the present invention have been described above in order to facilitate understanding of the present invention without limiting the present invention. The present invention can be changed or improved without departing from the gist thereof, and obviously, the equivalents of the present invention are included in the present invention. It is possible to arbitrarily combine or omit respective constituent elements described in the claims and specification in a range in which at least a part of the above-described problems can be solved, or a range in which at least a part of the effects is exhibited.

As one embodiment, this application discloses a hand for holding a substrate that includes a hand main body and a plurality of seating members. The plurality of seating members are mounted on the hand main body and on which the substrate is to be seated. Each of the plurality of seating members includes a shaft member and a lever member. The shaft member is supported to the hand main body. The lever member is supported to the shaft member and has a first end portion and a second end portion. The first end portion includes a seating portion on which the substrate is to be seated. The second end portion is disposed on a side opposite to the first end portion across the shaft member. At least a part of the plurality of seating members further includes a biasing member and a seating sensor. The biasing member is for giving a force of rotating the lever member to the lever member such that the second end portion moves downward. The seating sensor is configured to detect an upward movement of the second end portion.

Furthermore, as one embodiment, this application discloses a hand as follows. A magnet is disposed on the second end portion of the lever member. The seating sensor includes a magnetic sensor configured to detect an upward movement of the magnet.

Furthermore, as one embodiment, this application discloses a hand as follows. The seating sensor includes an optical sensor that includes a light projecting component and a light receiving component. The lever member is supported to the shaft member so as to block between the light projecting component and the light receiving component when the second end portion moves upward.

Furthermore, as one embodiment, this application discloses a hand as follows. A first electric contact is disposed on the second end portion of the lever member. The seating sensor includes an electric sensor that includes a second electric contact in contact with the first electric contact when the second end portion moves upward.

Furthermore, as one embodiment, this application discloses a hand as follows. At least a part of the plurality of seating members further includes a housing configured to cover the second end portion of the lever member and the seating sensor.

Furthermore, as one embodiment, this application discloses a hand as follows. The plurality of seating members are mounted on the hand main body at predetermined intervals with one another so as to surround a seating region on which the substrate is to be seated. The lever member is supported to the shaft member such that the first end portion projects to the seating region.

Furthermore, as one embodiment, this application discloses a hand as follows. Each of the plurality of seating members includes a bearing and an elastic member. The bearing is for supporting both end portions of the shaft member. The elastic member is for supporting the bearing.

Furthermore, as one embodiment, this application discloses a hand that further includes a plurality of guiding members and a plurality of positioning members. The plurality of guiding members are mounted on the hand main body at predetermined intervals with one another so as to surround a seating region on which the substrate is to be seated. The plurality of positioning members are mounted on the hand main body at predetermined intervals with one another so as to surround the seating region. Each of the plurality of guiding members has a substrate receiving surface inclined downward toward the seating region. Each of the plurality of positioning members includes a positioning portion in contact with an outer edge of the seating region.

Furthermore, as one embodiment, this application discloses a hand as follows. Each of the plurality of positioning members includes a positioning post formed in a columnar shape.

Furthermore, as one embodiment, this application discloses a hand that further includes a supporting member and a hand support. The supporting member is for supporting the hand. The hand support is for mounting the hand on the supporting member. The hand support includes a first hand support and a second hand support. The first hand support is mounted on any one of the hand and the supporting member. The second hand support is mounted on another one of the hand and the supporting member. A bottom surface of the first hand support has a tapered surface inclined to taper off toward the second hand support. The second hand support has a coupling region into which the first hand support is inserted. The coupling region has a tapered surface inclined corresponding to the tapered surface of the first hand support.

Furthermore, as one embodiment, this application discloses a hand as follows. A cutout is formed in a side surface on a side of the second hand support of the first hand support. The coupling region includes a protrusion having a tapered surface inclined corresponding to a tapered surface formed in the cutout.

Furthermore, as one embodiment, this application discloses a transfer apparatus that includes the hand according to any one of them described above and a driving mechanism. The driving mechanism is for moving the hand.

Furthermore, as one embodiment, this application discloses a substrate processing apparatus that includes a polishing device, a cleaning device, and the transfer apparatus. The polishing device is configured to polish a substrate. The cleaning device is configured to clean the substrate. The transfer apparatus according to any one of them described above configured to transfer the substrate processed by the polishing device or the cleaning device.

Furthermore, as one embodiment, this application discloses a hand that includes a hand main body and a plurality of seating members. The plurality of seating members are mounted on the hand main body and on which the substrate is to be seated. Each of the plurality of seating members includes a shaft member, a lever member, a bearing, and an elastic member. The shaft member is supported to the hand main body. The lever member is supported to the shaft member and has a first end portion and a second end portion. The first end portion includes a seating portion on which the substrate is to be seated. The second end portion is disposed on a side opposite to the first end portion across the shaft member. The bearing is for supporting both end portions of the shaft member. The elastic member is for supporting the bearing.

Furthermore, as one embodiment, this application discloses a hand as follows. The bearing includes a pair of bearings for supporting respective both the end portions of the shaft member. The elastic member includes a pair of elastic members for supporting the respective pair of bearings.

Furthermore, as one embodiment, this application discloses a hand as follows. The bearing includes a single bearing extending across both the end portions of the shaft member below the shaft member. The elastic member includes a single elastic member configured to support a center of a lower surface of the single bearing.

Furthermore, as one embodiment, this application discloses a hand as follows. At least a part of the plurality of seating members further includes a biasing member and a seating sensor. The biasing member is for giving a force of rotating the lever member to the lever member such that the second end portion moves downward. The seating sensor is configured to detect an upward movement of the second end portion.

Furthermore, as one embodiment, this application discloses a hand as follows. A magnet is disposed on the second end portion of the lever member. The seating sensor includes a magnetic sensor configured to detect an upward movement of the magnet.

Furthermore, as one embodiment, this application discloses a hand as follows. The seating sensor includes an optical sensor that includes a light projecting component and a light receiving component. The lever member is supported to the shaft member so as to block between the light projecting component and the light receiving component when the second end portion moves upward.

Furthermore, as one embodiment, this application discloses a hand as follows. A first electric contact is disposed on the second end portion of the lever member. The seating sensor includes an electric sensor that includes a second electric contact in contact with the first electric contact when the second end portion moves upward.

Furthermore, as one embodiment, this application discloses a hand as follows. At least a part of the plurality of seating members further includes a housing configured to cover the second end portion of the lever member and the seating sensor.

Furthermore, as one embodiment, this application discloses a hand as follows. The plurality of seating members are mounted on the hand main body at predetermined intervals with one another so as to surround a seating region on which the substrate is to be seated. The lever member is supported to the shaft member such that the first end portion projects to the seating region.

Furthermore, as one embodiment, this application discloses a hand that further includes a plurality of guiding members and a plurality of positioning members. The plurality of guiding members are mounted on the hand main body at predetermined intervals with one another so as to surround a seating region on which the substrate is to be seated. The plurality of positioning members are mounted on the hand main body at predetermined intervals with one another so as to surround the seating region. Each of the plurality of guiding members has a substrate receiving surface inclined downward toward the seating region. Each of the plurality of positioning members includes a positioning portion in contact with an outer edge of the seating region.

Furthermore, as one embodiment, this application discloses a hand as follows. Each of the plurality of positioning members includes a positioning post formed in a columnar shape.

Furthermore, as one embodiment, this application discloses a hand that further includes a supporting member and a hand support. The supporting member is for supporting the hand. The hand support is for mounting the hand on the supporting member. The hand support includes a first hand support and a second hand support. The first hand support is mounted on any one of the hand and the supporting member. The second hand support is mounted on another one of the hand and the supporting member. A bottom surface of the first hand support has a tapered surface inclined to taper off toward the second hand support. The second hand support has a coupling region into which the first hand support is inserted. The coupling region has a tapered surface inclined corresponding to the tapered surface of the first hand support.

Furthermore, as one embodiment, this application discloses a hand as follows. A cutout is formed in a side surface on a side of the second hand support of the first hand support. The coupling region includes a protrusion having a tapered surface inclined corresponding to a tapered surface formed in the cutout.

Furthermore, as one embodiment, this application discloses a transfer apparatus that includes the hand according to any one of them described above and a driving mechanism. The driving mechanism is for moving the hand.

Furthermore, as one embodiment, this application discloses a substrate processing apparatus that includes a polishing device, a cleaning device, and the transfer apparatus. The polishing device is configured to polish a substrate. The cleaning device is configured to clean the substrate. The transfer apparatus according to any one of them described above configured to transfer the substrate processed by the polishing device or the cleaning device.

As one embodiment, this application discloses a hand for holding a substrate that includes a hand main body, a plurality of seating members, a plurality of guiding members, and a plurality of positioning members. The plurality of seating members are mounted on the hand main body and on which the substrate is to be seated. The plurality of guiding members are mounted on the hand main body at predetermined intervals with one another so as to surround a seating region on which the substrate is to be seated. The plurality of positioning members are mounted on the hand main body at predetermined intervals with one another so as to surround the seating region. Each of the plurality of guiding members has a substrate receiving surface inclined downward toward the seating region. Each of the plurality of positioning members includes a positioning portion in contact with an outer edge of the seating region.

Furthermore, as one embodiment, this application discloses a hand as follows. Each of the plurality of positioning members includes a positioning post formed in a columnar shape.

Furthermore, as one embodiment, this application discloses a hand as follows. Each of the plurality of seating members includes a shaft member and a lever member. The shaft member is supported to the hand main body. The lever member is supported to the shaft member and has a first end portion and a second end portion. The first end portion includes a seating portion on which the substrate is to be seated. The second end portion is disposed on a side opposite to the first end portion across the shaft member. At least a part of the plurality of seating members further includes a biasing member and a seating sensor. The biasing member is for giving a force of rotating the lever member to the lever member such that the second end portion moves downward. The seating sensor is configured to detect an upward movement of the second end portion.

Furthermore, as one embodiment, this application discloses a hand as follows. A magnet is disposed on the second end portion of the lever member. The seating sensor includes a magnetic sensor configured to detect an upward movement of the magnet.

Furthermore, as one embodiment, this application discloses a hand as follows. The seating sensor includes an optical sensor that includes a light projecting component and a light receiving component. The lever member is supported to the shaft member so as to block between the light projecting component and the light receiving component when the second end portion moves upward.

Furthermore, as one embodiment, this application discloses a hand as follows. A first electric contact is disposed on the second end portion of the lever member. The seating sensor includes an electric sensor that includes a second electric contact in contact with the first electric contact when the second end portion moves upward.

Furthermore, as one embodiment, this application discloses a hand as follows. At least a part of the plurality of seating members further includes a housing configured to cover the second end portion of the lever member and the seating sensor.

Furthermore, as one embodiment, this application discloses a hand as follows. The plurality of seating members are mounted on the hand main body at predetermined intervals with one another so as to surround a seating region on which the substrate is to be seated. The lever member is supported to the shaft member such that the first end portion projects to the seating region.

Furthermore, as one embodiment, this application discloses a hand as follows. Each of the plurality of seating members includes a bearing and an elastic member. The bearing is for supporting both end portions of the shaft member. The elastic member is for supporting the bearing.

Furthermore, as one embodiment, this application discloses a hand that further includes a supporting member and a hand support. The supporting member is for supporting the hand. The hand support is for mounting the hand on the supporting member. The hand support includes a first hand support and a second hand support. The first hand support is mounted on any one of the hand and the supporting member. The second hand support is mounted on another one of the hand and the supporting member. A bottom surface of the first hand support has a tapered surface inclined to taper off toward the second hand support. The second hand support has a coupling region into which the first hand support is inserted. The coupling region has a tapered surface inclined corresponding to the tapered surface of the first hand support.

Furthermore, as one embodiment, this application discloses a hand as follows. A cutout is formed in a side surface on a side of the second hand support of the first hand support. The coupling region includes a protrusion having a tapered surface inclined corresponding to a tapered surface formed in the cutout.

Furthermore, as one embodiment, this application discloses a transfer apparatus that includes the hand according to any one of them described above and a driving mechanism. The driving mechanism is for moving the hand.

Furthermore, as one embodiment, this application discloses a substrate processing apparatus that includes a polishing device, a cleaning device, and the transfer apparatus. The polishing device is configured to polish a substrate. The cleaning device is configured to clean the substrate. The transfer apparatus according to any one of them described above is configured to transfer the substrate processed by the polishing device or the cleaning device.

### REFERENCE SIGNS LIST

6 . . . first linear transporter (transfer apparatus)
7 . . . second linear transporter (transfer apparatus)
600 . . . hand
600-1 . . . first hand
600-2 . . . second hand
600-3 . . . third hand
600-4 . . . fourth hand
610 . . . supporting member
620 . . . hand main body
630 . . . seating member
631 . . . pedestal
632 . . . shaft member
634 . . . lever member
634-1 . . . first end portion
634-1a . . . seating portion
634-2 . . . second end portion
634-2a . . . magnet
635 . . . elastic member
636 . . . biasing member
638 . . . seating sensor
639 . . . housing
640 . . . guiding member
641 . . . guide main body
642 . . . substrate receiving surface
680 . . . driving mechanism
650 . . . positioning member
652 . . . positioning portion
654 . . . positioning post
660 . . . hand support
670 . . . hand support
672 . . . first hand support
672c . . . tapered surface
672d . . . cutout
672e . . . tapered surface
672f . . . bottom surface
672g . . . side surface
674 . . . second hand support
674-1c . . . tapered surface
674-2d . . . protrusion
674-2e . . . tapered surface
674c . . . coupling region
1000 . . . CMP apparatus
SA . . . seating region
W . . . substrate

What is claimed is:

1. A hand for holding a substrate comprising:
a hand main body; and
a plurality of seating members mounted on the hand main body and on which the substrate is to be seated, wherein
each of the plurality of seating members includes a shaft member and a lever member, the shaft member is supported to the hand main body, the lever member is supported to the shaft member and has a first end portion and a second end portion, the first end portion includes a seating portion on which the substrate is to be seated, and the second end portion is disposed on a side opposite to the first end portion across the shaft member, and
at least a part of the plurality of seating members further includes a biasing member and a seating sensor, the biasing member is for giving a force of rotating the lever member to the lever member such that the second end portion moves downward, and the seating sensor is configured to detect an upward movement of the second end portion.

2. The hand according to claim 1, wherein
a magnet is disposed on the second end portion of the lever member, and
the seating sensor includes a magnetic sensor configured to detect an upward movement of the magnet.

3. The hand according to claim 1, wherein
the seating sensor includes an optical sensor that includes a light projecting component and a light receiving component, and
the lever member is supported to the shaft member so as to block between the light projecting component and the light receiving component when the second end portion moves upward.

4. The hand according to claim 1, wherein
a first electric contact is disposed on the second end portion of the lever member, and
the seating sensor includes an electric sensor that includes a second electric contact in contact with the first electric contact when the second end portion moves upward.

5. The hand according to claim 1, wherein
at least a part of the plurality of seating members further includes a housing configured to cover the second end portion of the lever member and the seating sensor.

6. The hand according to claim 1, wherein
the plurality of seating members are mounted on the hand main body at predetermined intervals with one another so as to surround a seating region on which the substrate is to be seated, and
the lever member is supported to the shaft member such that the first end portion projects to the seating region.

7. The hand according to claim 1, wherein
each of the plurality of seating members includes a bearing and an elastic member, the bearing is for supporting both end portions of the shaft member, and the elastic member is for supporting the bearing.

8. The hand according to claim 1, further comprising:
a plurality of guiding members mounted on the hand main body at predetermined intervals with one another so as to surround a seating region on which the substrate is to be seated; and
a plurality of positioning members mounted on the hand main body at predetermined intervals with one another so as to surround the seating region, wherein
each of the plurality of guiding members has a substrate receiving surface inclined downward toward the seating region, and
each of the plurality of positioning members includes a positioning portion in contact with an outer edge of the seating region.

9. The hand according to claim 8, wherein
each of the plurality of positioning members includes a positioning post formed in a columnar shape.

10. The hand according to claim 1, further comprising:
a supporting member for supporting the hand; and
a hand support for mounting the hand on the supporting member, wherein
the hand support includes a first hand support and a second hand support, the first hand support is mounted on any one of the hand and the supporting member, and the second hand support is mounted on another one of the hand and the supporting member,
a bottom surface of the first hand support has a tapered surface inclined to taper off toward the second hand support, and
the second hand support has a coupling region into which the first hand support is inserted, and the coupling region has a tapered surface inclined corresponding to the tapered surface of the first hand support.

11. The hand according to claim 10, wherein
a cutout is formed in a side surface on a side of the second hand support of the first hand support, and
the coupling region includes a protrusion having a tapered surface inclined corresponding to a tapered surface formed in the cutout.

12. A transfer apparatus comprising:
the hand according to claim 1; and
a driving mechanism for moving the hand.

13. A substrate processing apparatus comprising:
a polishing device configured to polish a substrate;
a cleaning device configured to clean the substrate; and
the transfer apparatus according to claim 12 configured to transfer the substrate processed by the polishing device or the cleaning device.

14.-41. (canceled)

42. The hand according to claim 1, further comprising:
a plurality of guiding members mounted on the hand main body at predetermined intervals with one another so as to surround a seating region on which the substrate is to be seated; and
a plurality of positioning members mounted on the hand main body at predetermined intervals with one another so as to surround the seating region, wherein
each of the plurality of guiding members has a substrate receiving surface inclined downward toward the seating region, and
each of the plurality of positioning members includes a positioning portion in contact with an outer edge of the seating region.

43. A hand for holding a substrate comprising:
a hand main body; and
a plurality of seating members mounted on the hand main body and on which the substrate is to be seated, wherein
each of the plurality of seating members includes a shaft member, a lever member, a bearing, and an elastic member, the shaft member is supported to the hand main body, the lever member is supported to the shaft member and has a first end portion and a second end portion, the first end portion includes a seating portion on which the substrate is to be seated, and the second end portion is disposed on a side opposite to the first end portion across the shaft member, the bearing is for supporting both end portions of the shaft member, and the elastic member is for supporting the bearing.

44. The hand according to claim 43, wherein
the bearing includes a pair of bearings for supporting respective both the end portions of the shaft member, and
the elastic member includes a pair of elastic members for supporting the respective pair of bearings.

45. The hand according to claim 43, wherein
the bearing includes a single bearing extending across both the end portions of the shaft member below the shaft member, and
the elastic member includes a single elastic member configured to support a center of a lower surface of the single bearing.

46. A hand for holding a substrate, comprising:
a hand main body;
a plurality of seating members mounted on the hand main body and on which the substrate is to be seated;
a plurality of guiding members mounted on the hand main body at predetermined intervals with one another so as to surround a seating region on which the substrate is to be seated; and
a plurality of positioning members mounted on the hand main body at predetermined intervals with one another so as to surround the seating region, wherein
each of the plurality of guiding members has a substrate receiving surface inclined downward toward the seating region, and
each of the plurality of positioning members includes a positioning portion in contact with an outer edge of the seating region.

47. The hand according to claim 46, wherein
each of the plurality of positioning members includes a positioning post formed in a columnar shape.
